(19) United States
(12) Patent Application Publication
(10) Pub. No.: US 2006/0189169 A1
(43) Pub. Date: Aug. 24, 2006

(54) Method for heat treatment of silicon wafers

(76) Inventors: Naoshi Adachi, Tokyo (JP); Yukio Komatsu, Tokyo (JP)

Correspondence Address: CLARK & BRODY, 1090 VERMONT AVENUE, NW, SUITE 250, WASHINGTON, DC, 20005, US

(21) Appl. No.: 11/355,946

(22) Filed: Feb. 17, 2006

(30) Foreign Application Priority Data
Feb. 18, 2005 (JP) 2005-041513
Aug. 12, 2005 (JP) 2005-234107

(51) Int. Cl. H01L 21/324

(52) U.S. Cl. 438/795

(57) ABSTRACT

A method is provided for the heat treatment of low oxygen concentration silicon wafers obtained from a silicon single crystal produced by the Czochralski process. The method comprises high-temperature oxidation heat treatment for the formation of a high oxygen concentration region under the wafer surface and the subsequent oxygen precipitation heat treatment. The high-temperature oxidation heat treatment can cause inward diffusion of oxygen from the wafer surface to form a region increased in oxygen concentration under the wafer surface, and the subsequent oxygen precipitation heat treatment can form a DZ layer on the wafer surface and stably form oxygen precipitates optimal in size within the wafer at a high density, so that excellent gettering effects can be produced. Further, in case of using as SOI substrates formed by SIMOX, too, the same effects as mentioned above can be produced by carrying out the high-temperature oxidation heat treatment after oxygen ion implantation in the SIMOX process and then carrying out the oxygen precipitation heat treatment.

### BACKGROUND OF THE INVENTION

1. Field of the Invention

This invention relates to a method for heat treatment of silicon wafers having a low oxygen concentration and, more particularly, to a method for heat treatment of silicon wafers wherein a silicon wafer having a low oxygen concentration and having a defect-free region all over the whole surface thereof is subjected to oxidation heat treatment at high temperature for formation of a high oxygen concentration region in the vicinity of the surface and the subsequent oxygen precipitation heat treatment, whereby a defect-free layer (denuded zone (DZ) layer) can be formed on the wafer surface and oxide precipitate (bulk micro defect (BMD)) formation within the wafer can be promoted.

2. Description of the Related Art

In recent years, the levels of quality requirements imposed on silicon single crystals produced by the Czochralski process (hereinafter, “CZ process”) serving as device substrates have been increasing with an increase in level of integration of semiconductor circuits and miniaturization of devices as promoted thereby. In particular, grown-in defects such as crystal originated particles (COPs) and dislocation clusters deteriorate gate oxide integrity and other device characteristics, so that it is important to manufacture defect-free wafers having no such grown-in defects in device-forming regions. As regards silicon-on-insulator (SOI) substrates as well, it has been recently desired that wafers having no micro defects due to the grown-in defects on and inside the SOI layer be manufactured. In forming this SOI structure, the SIMOX (separation by implanted oxygen) technique is now in wide use.

There are two basic classes of technique available for the manufacture of such defect-free wafers. As the first technique, there is a method based on wafer annealing which comprises the step of subjecting wafers to heat treatment in a hydrogen gas or argon gas atmosphere at elevated temperatures to thereby cause grown-in defects to disappear from the wafer surface layer for denuded zone layer formation. As the second technique, there is a method comprising the step of growing a perfect crystal having no grown-in defects in a single crystal ingot growing step in the CZ process and slicing off defect-free wafers from the defect-free zone of the crystal.

In case of annealed wafers obtained by the first technique, the denuded zone layer formed on the wafer surface layer is limited to about 20 μm in thickness and, therefore, it is impossible to form a defect-free zone deep within the wafer. In cases where it is required that a defect-free zone be formed to a level deep from the wafer surface, the first technique cannot cope with such a requirement.

In case of defect-free wafers obtained by the second technique, a defect-free zone can be formed from the wafer surface to the reverse side. It is necessary, however, to properly eliminate vacancy type (Vacancy) point defects and interstitial silicon type (Interstitial-Si) point defects introduced into the silicon single crystal in the growing step in the CZ process.

Thus, in a silicon single crystal ingot, there are a region where interstitial silicon type point defects are dominant (hereinafter, “I region”) and a region where vacancy type point defects are dominant (hereinafter, “V region”), with a neutral region lying therebetween where atoms are neither too abundant nor too scarce.

The V region is a region where COPs are readily formed by vacancies due to a deficiency of silicon atoms; it causes deterioration in gate oxide integrity. The I region is a region where dislocation clusters are readily formed due to presence of silicon atoms in excess. The COPs and dislocation clusters are formed as aggregates of point defects where interstitial silicon atoms and vacancies are present in a supersaturated state, respectively. Even when there is slight uneven distribution in the number of atoms, however, they will never be formed in the neutral region which is in an unsaturated state.

FIG. 1 is a schematic illustration of a typical example of distribution of defects as observed on a silicon wafer. Shown in the figure are the results of observation, by X-ray topography, of the distribution of micro defects on the surface of a wafer which is sliced off from a single crystal just after growing, immersed in an aqueous solution of copper nitrate for depositing Cu and subjected to heat treatment.

In the V region of this wafer, oxidation-induced stacking faults (OSFs) are found in a ring-like form at a site about two thirds of the outside diameter and, inside of the ring, an oxygen precipitation promoted region (defect-free region) and COPs are found. Further, adjacent to and just outside of the ring-like OSFs, there is an oxygen precipitation promoted region (defect-free region) where an oxide is likely to be present. On the other hand, in the I region, adjacent to the oxygen precipitation promoted region mentioned above, there is an oxygen precipitation inhibited region (defect-free region) where no defects are found and, outside thereof, namely in a peripheral portion of the wafer, the formation of dislocation clusters is found.

FIG. 2 is a schematic illustration of the relation between a pulling rate in the growing step in the CZ process and locations of appearance of crystal defects. As shown in FIG. 2, the locations of appearance of such defects are greatly influenced by the pulling rate on the occasion of single crystal growing. Therefore, it is understood that FIG. 1 shows a section, at A in FIG. 2 and perpendicular to an axis of pulling up, of a single crystal or a wafer derived from the single crystal grown at that pulling rate.

If, in producing defect-free wafers by the second technique mentioned above, the oxygen precipitation promoted and defect-free regions adjacent to the ring-like OSFs that correspond to the neutral regions can be successfully expanded, it will be possible to eliminate grown-in defects including COPs and dislocation clusters.

FIG. 3 is a schematic illustration of relation between the pulling rate and the locations of occurrence of crystal defects in case of pulling up of a single crystal while improving temperature gradient conditions within the single crystal in the direction of the axis of pulling up. As shown in FIG. 3, by controlling temperature distribution within the single crystal just after solidification and thereby rendering a ring-like OSF formation region U-shaped, it is possible to inhibit either region, one being an I region and in which dislocation clusters are formed and the other being a V region and in which COPs are formed, from occurring in the wafer plane.

In case of a single crystal wafer grown at a pulling rate corresponding to B in a single crystal in FIG. 3, the wafer consists of defect-free regions, namely oxygen precipitation promoted regions, including a ring-like OSF formation region, and an oxygen precipitation inhibited region; thus COPs and dislocation clusters, which are grown-in defects, can be eliminated. Similarly, in case of a single crystal wafer grown at a pulling rate corresponding to C, the wafer is a defect-free wafer comprising a defect-free region outside the ring-like OSF formation region.

Meanwhile, a defect-free region can be formed from the wafer surface to the reverse side in a defect-free wafer but, when the oxygen concentration in the wafer is high, oxygen precipitates and OSFs are formed up to the vicinity of the wafer surface on which devices are formed in the device manufacturing process. Therefore, these act as factors deteriorating the device characteristics.

In Japanese Patent Application Publication No. 11-147786, a silicon wafer is proposed which has an oxygen concentration lower than 24 ppma (6.5 to 12×10¹⁷ atoms/cm³ (ASTM F 121-1979)) all over the wafer surface and in which latent nuclei for ring-like OSFs are present as a result of oxygen precipitation heat treatment but no ring-like OSFs will be formed upon thermal oxidation treatment and there are neither flow pattern defects (FPDs) nor interstitial dislocation loops all over the wafer surface.

However, the silicon wafer proposed in the above publication contains oxygen only at a low concentration, so that the formation of oxygen precipitates hardly occurs even upon low-temperature heat treatment of the wafer for the formation of oxygen precipitate nuclei, followed by high-temperature heat treatment for the growth of oxygen precipitate nuclei. As a result, any sufficient capacity of gettering cannot be exercised against heavy metal contamination.

Regarding the formation of an oxygen precipitate layer having a gettering effect, International laid-open patent application WO98/38675 proposes a method of uniformly forming a DZ layer, which comprises subjecting the silicon wafer surface to a short period of heat treatment involving rapid heating and rapid cooling (rapid thermal annealing; RTA) in a specified atmospheric gas to thereby freeze thermally equilibrated vacancies at a high concentration within the wafer by rapid cooling, followed by heat treatment for the outward diffusion of the vacancies on the surface. As disclosed therein, the heat treatment at a temperature lower than the RTA treatment temperature after DZ layer is formed results in the formation of oxygen precipitate nuclei as an internal defect layer.

However, the initial oxygen concentration enabling the formation of oxygen precipitate nuclei by vacancy freezing in rapid thermal annealing is down to about 7×10¹⁷ atoms/cm³ (ASTM F 121-1979), and no oxygen precipitates are formed in wafers having a lower oxygen concentration. Therefore, it was impossible to cause the wafer inside to have a gettering capacity.

Further, regarding the production of defect-free wafers, Japanese Patent Application Publication No. 2003-100762 proposes a method of producing silicon wafers which comprises the step of subjecting defect-free crystal wafers to high-temperature heat treatment in an argon gas atmosphere to eliminate grown-in defects remaining in small numbers in the wafers. Further, Japanese Patent Application Publication No. 2003-77925 proposes a method of producing silicon wafers which comprises the step of subjecting defect-free crystal wafers to high-temperature heat treatment in a nitrogen-containing gas atmosphere for the introduction of vacancies into the silicon wafer inside and to precipitation treatment for the precipitation of oxygen in the internal vacancies.

However, the production methods proposed in Japanese Patent Application Publication Nos. 2003-100762 and 2003-77925 cannot form oxygen precipitates to a sufficient extent within the wafer when the wafer obtained has a low oxygen concentration. Further, when the oxygen concentration in the wafer is high, oxygen precipitates can be formed within the wafer but the oxygen precipitates formed show a distribution such that the BMD density decreases from the central portion of the wafer toward the surface, and the distance from the position corresponding to the BMD density peak (central position of the wafer) to the wafer surface becomes long and the gettering capacity decreases accordingly.

### SUMMARY OF THE INVENTION

As discussed hereinabove, when, in case of a defect-free wafer being employed as a device substrate, the oxygen concentration in the wafer is high, oxygen precipitates and OSFs are formed up to the vicinity of the wafer surface where devices are formed in the device manufacturing process; they deteriorate the device characteristics. Therefore, the defect-free wafer high in oxygen concentration as such cannot be applied as the device substrate.

On the other hand, even when a defect-free wafer with a low oxygen concentration is employed and subjected to RTA treatment using a lamp annealing furnace to secure the gettering capacity, the initial oxygen concentration at which oxygen precipitate formation is possible through vacancy freezing is down to about 7×10¹⁷ atoms/cm³ (ASTM F 121-1979)). Therefore, with a wafer having an initial oxygen concentration lower than the above level, no oxygen precipitate can be formed, hence the inside of a wafer cannot be provided with the gettering capacity.

It is an object of the present invention, which has been made in view of the above-discussed problems with defect-free wafers, to provide a method for heat treatment of silicon wafers which makes it possible to form a DZ layer on a wafer surface and promote formation of oxygen precipitates within the wafer by carrying out, under optimal conditions, an oxidation heat treatment at high temperature for forming a high oxygen concentration region under the surface and the subsequent oxygen precipitation heat treatment, even when a defect-free wafer having a low oxygen concentration is employed.

The present inventors made investigations to accomplish the above object and, as a result, found that even when a wafer with a low oxygen concentration is used, a region increased in oxygen concentration can be formed under the wafer surface by subjecting the wafer to high-temperature heat treatment in an oxygen atmosphere to thereby cause inward diffusion of oxygen from the silicon wafer surface and the subsequent heat treatment can result in stable formation of oxygen precipitates and thus in an improvement of gettering capacity. They have completed the present invention based on such findings.

Thus, the heat treatment method by the present invention is the one which comprises the step of subjecting silicon wafers obtained from a silicon single crystal produced by the CZ process with an oxygen concentration of 6.5 to 12×10¹⁷ atoms/cm³ (ASTM F 121-1979) to said heat treatment and is characterized in that the silicon wafers are subjected to the oxidation heat treatment at high temperature for the formation of a high oxygen concentration region under the wafer surface and then to oxide precipitation heat treatment.

For causing the diffusion of oxygen from the silicon wafer surface toward the inside, it is necessary to increase the solubility of oxygen to a level higher than the oxygen concentration in the silicon wafer. The solubility of oxygen in the silicon wafer depends on the wafer temperature, and the solubility of oxygen increases as the temperature rises. For example, the solubility of oxygen is 18×10¹⁷ atoms/cm³ when the wafer temperature is 1350° C., the solubility of oxygen at 1300° C. is 10.1×10¹⁷ atoms/cm³, the solubility of oxygen at 1250° C. is 8.49×10¹⁷ atoms/cm³, the solubility of oxygen at 1200° C. is 5.73×10¹⁷ atoms/cm³, and the solubility of oxygen at 700° C. is 1.23×10¹⁵ atoms/cm³.

Therefore, according to the heat treatment method by the present invention, the oxidation heat treatment at high temperature is carried out at a temperature of 1250° C. to 1380° C. in a gas atmosphere containing 5% or more of oxygen for 1 to 20 hours to thereby cause diffusion of oxygen from the wafer surface toward the inside, whereby a region increased in oxide concentration can be formed inside of the wafer.

On the other hand, for formation of buried oxide film in a region implanted with oxygen ions from a silicon substrate surface in a step of forming SOI substrates by SIMOX (separation by implanted oxygen), it becomes necessary to carry out the annealing heat treatment at a temperature not lower than 1300° C. in an oxidizing atmosphere for 4 hours to 48 hours. In particular, for promoting growth of the buried oxide film, it is necessary to secure an oxygen concentration of 20% or higher in the oxidizing atmosphere. Such an oxygen concentration can result in a sufficient extent of diffusion of oxygen from the wafer surface toward the inside and, as a result, oxide precipitates can be readily formed in the subsequent precipitation heat treatment step.

In the heat treatment method by the present invention, the oxygen precipitation heat treatment following the formation of a high oxygen concentration region comprises the heat treatment for formation of oxygen precipitate nuclei, which is to be carried out in an atmosphere of oxygen, nitrogen, inert gas, or mixed gas in combination at a temperature of 450° C. to 800° C. for 1 to 48 hours, and the subsequent heat treatment for growth of oxygen precipitate nuclei, which is to be carried out in an atmosphere of oxygen, nitrogen, inert gas, or mixed gas in combination at a temperature of 800 to 1100° C. for 4 to 48 hours. The oxygen precipitation heat treatment comprising the above-mentioned two-step heat treatment can result in stable formation of oxygen precipitates optimal in size at a high density.

In the heat treatment method by the present invention, prior to the above-mentioned oxygen precipitation heat treatment, the heat treatment can be carried out in a nitrogen gas-containing atmosphere at a temperature of 1100 to 1300° C. at temperature raising and lowering rates of not lower than 20° C./second for 1 second to 5 minutes using a rapid thermal annealing heater. When such rapid thermal annealing (RTA) is carried out in nitrogen-containing atmospheric gas, vacancies can be newly formed within the wafer and, therefore, the subsequent oxygen precipitation heat treatment can give silicon wafers an excellent gettering effect.

In the heat treatment method by the present invention, defect-free wafers without the occurrence of grown-in defects are used. Thus, the method is characterized by using those silicon wafers which are obtained from a silicon single crystal made of a defect-free region where neither dislocation clusters, which are aggregates of interstitial silicon type point defects appearing in the I region, nor COPs, which are aggregates of vacancy type point defects appearing in the V region, are present.

Furthermore, in the heat treatment method by the present invention, silicon wafers obtained from a silicon single crystal containing nitrogen within the concentration range of 1×10¹² to 5×10¹⁵ atoms/cm³, or from a silicon single crystal containing carbon within the concentration range of 1×10¹⁵ to 5×10¹⁶ atoms/cm³ (ASTM F 123-1981) can be used as the low oxygen concentration silicon wafers mentioned above.

In accordance with the silicon wafer heat treatment method by the present invention, even when defect-free wafers with low oxygen concentration are employed, inward diffusion of oxygen from the wafer surface can be caused so as to form a region increased in oxygen concentration under the wafer surface by subjecting the wafers to high-temperature oxidation heat treatment under appropriate conditions and, therefore, when the subsequent oxygen precipitation heat treatment is carried out under optimal conditions, a DZ layer can be formed on the wafer surface, oxygen precipitates optimal in size can be formed stably at a high density within the wafer and, thus, excellent gettering effects can be produced. Furthermore, the method can also be applied to annealing heat treatment of SOI substrates formed by SIMOX.

### BRIEF DESCRIPTION OF THE DRAWINGS

FIG. 1 is a schematic illustration of a typical example of distribution of defects as observed on a silicon wafer.

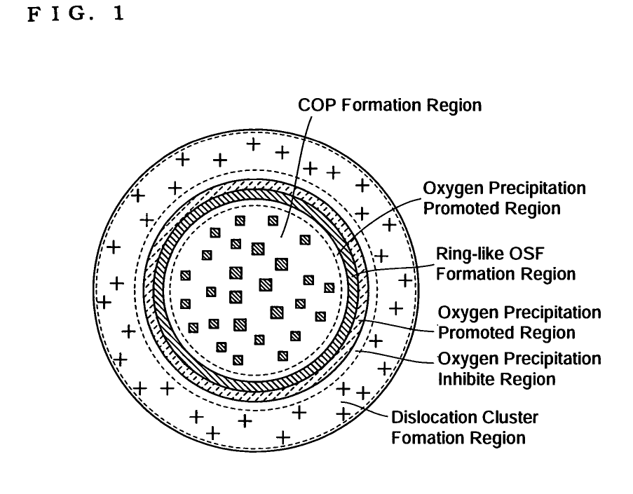

FIG. 2 is a schematic illustration of relation between a pulling rate in a growing step in the CZ process and locations of appearance of crystal defects.

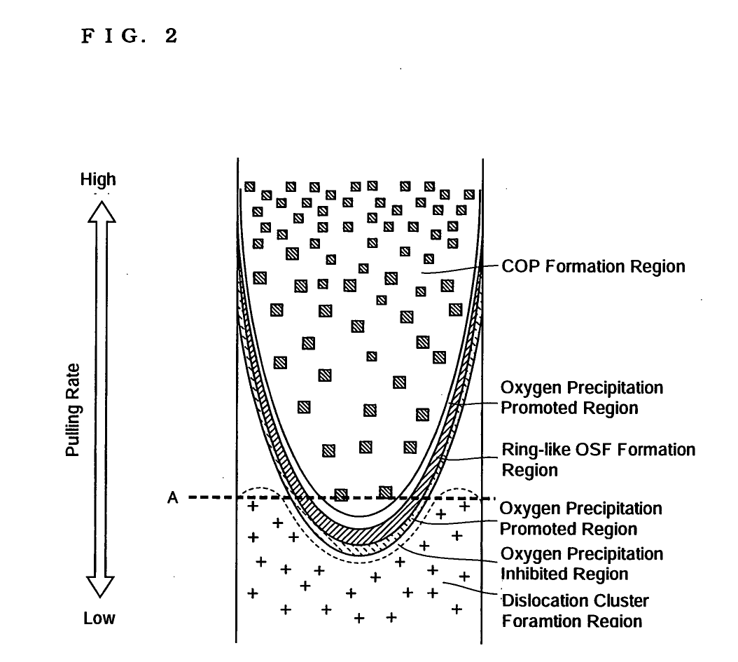

FIG. 3 is a schematic illustration of the relation between the pulling rate and the locations of occurrence of crystal defects in case of pulling up of a single crystal while improving temperature gradient conditions within the single crystal in the direction of an axis of pulling up.

FIG. 4 is a schematic illustration of crystal regions of a defect-free wafer to be pertinent to the present invention.

FIG. 5 is a schematic illustration of a sectional configuration of a silicon wafer obtained by the heat treatment method by the present invention.

### DETAILED DESCRIPTION OF THE PREFERRED EMBODIMENTS

The silicon wafer heat treatment method by the present invention is the one for heat treatment of low oxygen concentration silicon wafers obtained from a silicon single crystal produced by the CZ process. The method comprises the step of subjecting such silicon wafers to high temperature heat treatment in an oxygen atmosphere to thereby cause inward diffusion of oxygen from the wafer surface to form a high oxygen concentration region within the wafer. In the following, the contents of the present invention are described with respect to the pertinent wafers, high-temperature oxidation heat treatment, oxygen precipitation heat treatment and RTA treatment.

1. Re: Characteristics and Crystal Regions of Pertinent Wafers

The upper limit to the oxygen concentration of the low oxygen concentration silicon wafers to be pertinent to the present invention is set at 12×10¹⁷ atoms/cm³ (ASTM F 121-1979). However, in case where the oxygen concentration is lower than 4×10¹⁷ atoms/cm³, the oxygen precipitate density itself markedly decreases and oxygen precipitation itself becomes unlikely to occur. It is therefore necessary for the oxygen concentration to be not lower than 4×10¹⁷ atoms/cm³. Furthermore, when the oxygen concentration is lower than 6.5×10¹⁷ atoms/cm³, the wafer strength becomes decreased and the slip tends to occur. It is thus desirable that the oxygen concentration be not lower than 6.5×10¹⁷ atoms/cm³. From such oxygen precipitate density and wafer strength maintenance viewpoint, the lower limit to the oxygen concentration in the low oxygen concentration silicon wafers to be pertinent to the present invention is set at 6.5×10¹⁷ atoms/cm³.

When, on the other hand, the oxygen concentration exceeds 12×10¹⁷ atoms/cm³, oxygen precipitates and OSFs are formed in the wafer surface layer, possibly deteriorating the device characteristics. Therefore, the oxygen concentration in the silicon wafers to be pertinent to the present invention should be within the range of 6.5 to 12×10¹⁷ atoms/cm³.

It was found that, in cases where the silicon substrates of the present invention are used as SOI substrates formed by SIMOX, even high initial oxygen concentrations cause no problem, since the substrates are subjected to ultrahigh temperature heat treatment so that OSFs and oxygen precipitates are reduced in size or disappear. Thus, if the lower limit to the oxygen concentration is set at 6.5×10¹⁷ atoms/cm³, it is not necessary to set the upper limit thereto. However, excessively high oxygen concentrations tend to cause cracks and other problems from the manufacturing viewpoint. Therefore, it is desirable that the upper limit to the oxygen concentration be set at 1.8×10¹⁸ atoms/cm³.

Further, the silicon wafers to be pertinent to the present invention desirably contain nitrogen at a concentration within the range of 1×10¹² to 5×10¹⁵ atoms/cm³. When the wafers contain nitrogen, the BMD density becomes uniform all over the wafer surface and the growth of oxygen precipitates is promoted accordingly. For producing this effect, a nitrogen content of not lower than 1×10¹² atoms/cm³ is necessary and, on the other hand, a content exceeding 5×10¹⁵ atoms/cm³, which is a concentration close to the limit of the content of nitrogen in single crystals in view of the solubility thereof, makes it difficult to maintain the concentration thereof uniformly all over the full length of each single crystal. The nitrogen concentration so referred to herein is the value calculated form the segregation coefficient for nitrogen based on the initial amount of the molten silicon, the amount of nitrogen initially added to the molten silicon and sites of cutting wafers relative to the ingot.

Further, the silicon wafers to be pertinent to the present invention desirably contain carbon at a concentration within the range of 1×10¹⁵ to 5×10¹⁶ atoms/cm³ (ASTM F 123-1981). Carbon is electrically neutral and promotes the growth of oxygen precipitate nuclei having gettering potential and, at the same time, is effective in maintaining the wafer strength, which otherwise decreases as a result of a decrease in interstitial oxygen (dissolved oxygen) content upon heat treatment; therefore, carbon can be contained in the wafers. In this case, its effects are not produced to a satisfactory extent at the content level of lower than 1×10¹⁵ atoms/cm³ and, at excessively high content level, the single crystal growth by the CZ process tends to turn to polycrystallization, hence the carbon concentration is desirably not higher than 5×10¹⁶ atoms/cm³.

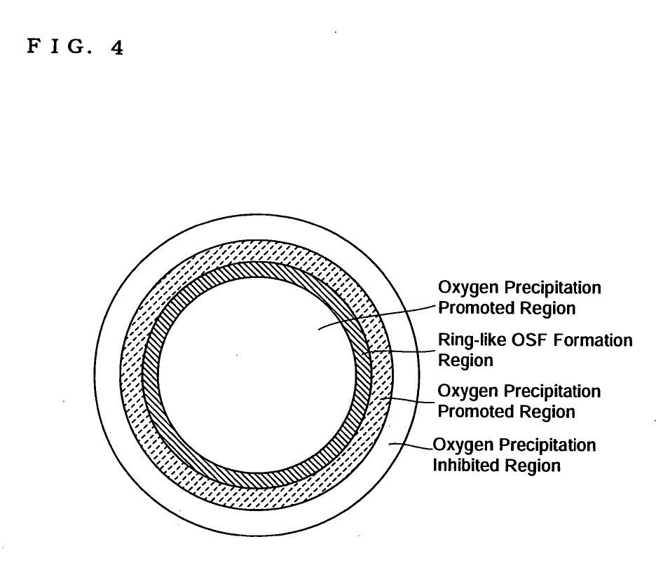

FIG. 4 is an exemplified schematic illustration of the crystal regions in a defect-free wafer to be pertinent to the present invention. Thus, the present invention is characterized by using such a defect-free wafer obtained from a silicon single crystal made of a defect-free region where neither dislocation clusters, which are aggregates of interstitial silicon type point defects appearing in the I region, nor COPs, which are aggregates of vacancy type point defects appearing in the V region, are present. In growing silicon single crystals free of dislocation clusters and COPs, the conventional pulling up conditions may be combined with such a technique as pulling up with water cooling or hydrogen doping, and the silicon single crystals thus obtained may also be used.

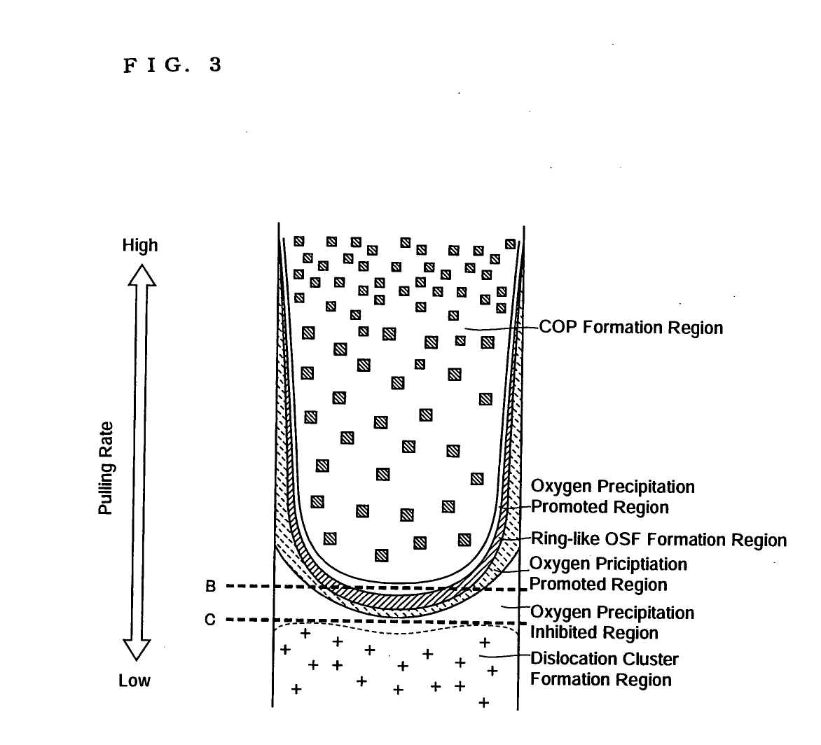

Therefore, as exemplified in FIG. 4, the crystal regions of the defect-free wafers to be pertinent to the present invention can correspond to the crystal regions of the wafer obtained from a single crystal grown at a pulling rate corresponding to B shown in FIG. 3 referred to hereinabove. The wafer is made of a defect-free region consisting of oxygen precipitation promoted regions, including a ring-like OSF formation region, and an oxygen precipitation inhibited region; grown-in defects, including dislocation clusters and COPs, are never present.

The method by the present invention can further be applied to the crystal regions of such a wafer as obtained from a single crystal grown at a single crystal pulling rate corresponding to C in FIG. 3 so long as there are no grown-in defects.

The results of measurement of dislocation cluster and COP densities depend on the evaluation methods. By saying “a crystal free of grown-in defects” herein, it is meant that the density as observed by the Cu decoration-based evaluation method is not higher than 3.0/cm². This evaluation method is higher in sensitivity than Secco etching and can detect dislocation clusters and COPs smaller in size as well.

2. Re: High-Temperature Oxidation Heat Treatment

In the heat treatment method by the present invention, the high-temperature oxidation heat treatment is carried out in a gas atmosphere containing at least 5% of oxygen at a temperature of 1250° C. to 1380° C. for 1 to 20 hours. When the oxygen concentration in the gas atmosphere used is less than 5%, the inward diffusion of oxygen from the wafer surface becomes insufficient, hence the oxygen content of not lower than 5% is required. Nitrogen and inert gases, among others, can be employed as the gas to be mixed in the gas atmosphere.

When the heating temperature in the high-temperature oxidation treatment is lower than 1250° C., no sufficient inward diffusion of oxygen can be induced. On the other hand, when the heating temperature is higher than 1380° C., the slip and/or warp may possibly occur in the wafers during heat treatment. Therefore, the heating temperature in the high-temperature oxidation heat treatment should be 1250° C. to 1380° C. A heating time shorter than 1 hour results in insufficient inward diffusion of oxygen, whereas even when heating is carried out for a longer period exceeding 20 hours, the effect of inward diffusion of oxygen reaches a point of saturation; hence the heating time should be 1 to 20 hours.

In the heat treatment method by the present invention, the temperature of the wafers to be taken out of the furnace after 1 to 20 hours of high-temperature oxidation heat treatment at 1250° C. to 1380° C. is generally within the range of 500° C. to 700° C. and, in the period during which the wafers are cooled to such temperature for taking out of the furnace, the oxygen concentration in the wafer surface layer drops in light of solubility of oxygen and outward diffusion of oxygen occurs in the wafer surface layer, whereby a DZ layer free of oxygen precipitates and OSFs is formed.

In case of SOI substrates formed by SIMOX, the high-temperature oxidation heat treatment is carried out in a gas atmosphere containing 20% or more of oxygen at a temperature of 1300° C. to 1380° C. for 4 to 48 hours. The heating temperature range of 1300° C. to 1380° C. is selected here because heat treatment at 1300° C. or above is necessary for forming a buried oxide film in the region implanted with oxygen ions from the silicon substrate surface and heat treatment at above 1380° C. may cause slip and/or warp in the wafers. The atmosphere is required to have an oxygen concentration of not lower than 20% so that the growth of the buried oxide film may be promoted.

3. Re: Oxygen Precipitation Heat Treatment and RTA Treatment

The oxygen precipitation heat treatment employed in the heat treatment method by the present invention comprises a combination of two steps of heat treatment, namely the first heat treatment for the formation of oxygen precipitate nuclei and the other heat treatment for the growth of oxygen precipitates. Here, the first heat treatment for the formation of oxygen precipitate nuclei is carried out in an atmosphere of oxygen, nitrogen, inert gas, or mixed gas under the conditions of 450° C. to 800° C.×1 to 48 hours. Even when the other high temperature heat treatment for growing oxygen precipitates is carried out immediately after the high-temperature oxidation heat treatment, oxygen precipitates with due size and showing a sufficient density cannot be formed since oxygen precipitate nuclei to serve as bases for oxygen precipitates are not yet present. Therefore, it is necessary to carry out, as a first step of heat treatment, the heat treatment at the temperature causing the formation of oxygen precipitate nuclei within the wafer.

The atmosphere to be used in the first heat treatment for formation of oxygen precipitate nuclei is oxygen, nitrogen, inert gas, or mixed gas. For securing a sufficient BMD size and BMD density, a treatment time of 1 to 48 hours, desirably 4 to 24 hours, is required.

Then, the other heat treatment for growth of oxygen precipitates is carried out in an atmosphere of oxygen, nitrogen, inert gas, or mixed gas under the conditions of 800 to 1100° C.×4 to 48 hours. If any oxygen precipitate nuclei remains in the state as formed, the minute oxygen precipitate nuclei may possibly disappear upon high-temperature heat treatment in the device manufacturing process. Therefore, it is necessary to carry out, as a second stage of heat treatment, the heat treatment at the temperature enabling the growth of the oxygen precipitate nuclei for the formation of oxygen precipitates with due size.

For the formation of oxygen precipitates with due size by growing the oxygen precipitate nuclei, the conditions of 800 to 1100° C.×4 to 48 hours are required. Generally, however, the conditions of 1000° C.×16 hours is considered as the standard evaluation conditions in evaluating wafers with respect to oxygen precipitates, and the heat treatment for the growth of oxygen precipitates can be carried out under the same conditions.

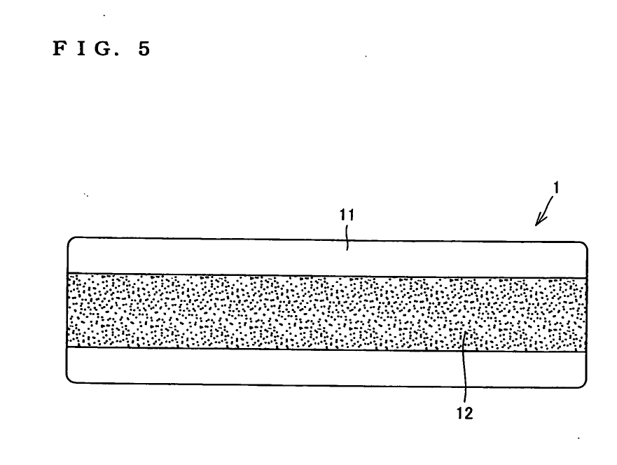

FIG. 5 is a schematic representation of the sectional configuration of a silicon wafer obtained by the heat treatment method according to the present invention. From surface layers of both sides of a silicon wafer 1, there are formed DZ layers 11 free of oxygen precipitates and OSFs as a result of outward diffusion of oxygen from wafer surface layers. Inside of these DZ layers, there is formed an oxygen precipitate layer 12 having a high BMD density as a result of the heat treatment for the growth of oxygen precipitates. This wafer 1 constitutes a defect-free wafer owing to the use of a silicon wafer obtained from a silicon single crystal free of dislocation clusters, which are aggregates of interstitial silicon type point defects, and of COPs, which are aggregates of vacancy type point defects.

Furthermore, in the heat treatment method by the present invention, RTA treatment can be carried out in a nitrogen gas-containing atmosphere at a temperature of 1100 to 1300° C. for 1 second to 5 minutes at temperature raising/lowering rates of 20° C./second or higher using a rapid thermal annealing heater. Vacancies are injected into the inside of wafer by this RTA treatment.

As mentioned hereinabove, the pertinent wafers are silicon wafers free of aggregates of point defects and, therefore, are almost free of interstitial silicon type point defects, which counteractively extinguish the vacancies injected thereinto, hence vacancies necessary for oxygen precipitation can be efficiently injected thereinto.

When the subsequent oxygen precipitation heat treatment is carried out, the oxygen precipitation into the vacancies is promoted, the oxygen precipitate nuclei are stabilized upon heat treatment, and the precipitates are grown. Thus, this RTA treatment makes it possible to render the oxygen precipitation in the wafer plane uniform and obtain an oxygen precipitate layer with a sufficient BMD density.

### EXAMPLES

The effects of the silicon wafer heat treatment method by the present invention are described referring to certain specific examples, namely Comparative Examples 1 and 2, and Inventive Examples 1 to 5 which are embodiments of the present invention.

### 1. COMPARATIVE EXAMPLES

### 1-1. Comparative Example 1

Low oxygen concentration wafers showing a specific resistance of 10 Ωcm and having respectively an oxygen concentration of one of three levels, namely 6.5×10¹⁷ atoms/cm³, 9×10¹⁷ atoms/cm³ and 12×10¹⁷ atoms/cm³ (ASTM F 121-1979), with a defect-free region spreading all over the surface, were prepared. These wafers were immediately subjected to heat treatment without high-temperature oxidation heat treatment wherein they were heated from 600° C. to 700° C. at a rate of 0.3° C./minute and, after holding 4 hours at the temperature, further heated to 1000° C. with duration of 8 hours.

### 1-2. Comparative Example 2

Low oxygen concentration wafers showing a specific resistance of 10 Ωcm and having respectively an oxygen concentration of one of two levels, namely 6.5×10¹⁷ atoms/cm³ and 10×10¹⁷ atoms/cm³ (ASTM F 121-1979), with a defect-free region spreading all over the surface, were prepared. These wafers were subjected to high-temperature heat treatment in a gas atmosphere containing 1% of oxygen (partial pressure of oxygen being 1%) at 1350° C. for 10 hours. Thereafter, they were heated from 600° C. to 700° C. at a rate of 0.3° C./minute and, after holding for 4 hours at the temperature, further heated to 1000° C. with duration of 16 hours, using a horizontal batch type furnace.

### 2. INVENTIVE EXAMPLES

### 2-1. Inventive Example 1

Low oxygen concentration wafers showing a specific resistance of 10 Ωcm and having respectively an oxygen concentration of one of three levels, namely 6.5×10¹⁷ atoms/cm³, 9×10¹⁷ atoms/cm³ and 12×10¹⁷ atoms/cm³ (ASTM F 121-1979), with a defect-free region spreading all over the surface, were prepared. These wafers were subjected to high-temperature oxidation heat treatment in an oxygen atmosphere (partial pressure of oxygen being 100%) at 1300° C. for 10 hours using a horizontal batch type furnace. Thereafter, the temperature was raised from 600° C. to 700° C. at a rate of 0.3° C./minute and, after holding for 4 hours at the temperature, further heated to 1000° C. with duration of 8 hours.

### 2-2. Inventive Example 2

Low oxygen concentration wafers showing a specific resistance of 10 Ωcm and having respectively an oxygen concentration of one of two levels, namely 6.5×10¹⁷ atoms/cm³ and 10×10¹⁷ atoms/cm³ (ASTM F 121-1979), with a defect-free region spreading all over the surface, were prepared. Using a horizontal batch type furnace, these wafers were subjected to high-temperature oxidation heat treatment in a gas atmosphere containing 50% of oxygen (partial pressure of oxygen being 50%) at 1350° C. for 10 hours. Thereafter, the temperature was raised from 600° C. to 700° C. at a rate of 0.3° C./minute and, after holding for 4 hours at the temperature, further heated to 1000° C. with duration of 16 hours.

### 2-3. Inventive Example 3

Low oxygen concentration wafers showing a specific resistance of 10 Ωcm and having respectively an oxygen concentration of one of two levels, namely 7.0×10¹⁷ atoms/cm³ and 10×10¹⁷ atoms/cm³ (ASTM F 121-1979), with a defect-free region spreading all over the surface, were prepared. Using a horizontal batch type furnace, these wafers were subjected to high-temperature oxidation heat treatment in a gas atmosphere containing 50% of oxygen (partial pressure of oxygen being 50%) at 1350° C. for 10 hours.

The wafers obtained were heated to 1200° C. at a temperature raising rate of 50° C./second in an ammonia gas atmosphere using a lamp annealing furnace and, after duration of 120 seconds, cooled to 400° C. at a rate of 50° C./second. Thereafter, using a horizontal batch type furnace, they were held at 800° C. for 4 hours and then further subjected to heat treatment by raising the temperature to 1000° C. with duration of 16 hours.

### 2-4. Inventive Example 4

Low oxygen concentration wafers showing a specific resistance of 10 Ωcm and having respectively an oxygen concentration of one of two levels, namely 7.0×10¹⁷ atoms/cm³ and 10×10¹⁷ atoms/cm³ (ASTM F 121-1979), with a defect-free region spreading all over the surface, were prepared. The wafers obtained were subjected to oxygen ion implantation; the implantation energy was 180 KeV, and the dose window was 4.0×10¹⁷/cm³.

According to the standard SIMOX annealing conditions, the oxygen-implanted wafers were charged at 700° C. and heated to 1350° C. in an argon gas-based atmosphere containing 1% of oxygen and, after duration of 5 hours, further held in an atmosphere containing 70% of oxygen for 10 hours and then cooled to 700° C. The wafers obtained were subjected to further heat treatment wherein they were heated from 600° C. to 700° C. at a rate of 0.3° C./minute and, after duration of 4 hours at that temperature, heated to 1000° C. with duration of 8 hours.

### 2-5. Inventive Example 5

The same wafers as used in Example 4 were used and subjected to oxygen ion implantation; the implantation energy was 180 KeV, and the dose window was 4.0×10¹⁷/cm³. The wafers were charged at 700° C. and heated to 1350° C. in an atmosphere containing 80% of oxygen and, after duration of 40 hours, cooled to 700° C. The wafers obtained were subjected to further heat treatment wherein they were heated from 600° C. to 700° C. at a rate of 0.3° C./minute and, after duration of 4 hours, heated to 1000° C. and held at that temperature for 8 hours.

### 3. EVALUATION RESULTS

The wafers obtained in Comparative Examples 1 and 2 and Inventive Examples 1 to 5 according to the invention were each cleaved into halves, followed by etching to a depth of 3 μm with a Wright etching solution. Each wafer section was observed for oxygen precipitates under an optical microscope. In Comparative Examples 1 and 2, almost no oxygen precipitates were observed. In each of Inventive Examples 1 to 5 according to the invention, oxygen precipitates could be observed at a density of 5×10⁹/cm³ or higher at a depth of about 100 μm from the surface corresponding to the oxygen concentration peak in inward diffusion of oxygen. Further, the occurrence of a DZ layer could be confirmed to a depth of about 50 μm from the wafer surface. In Inventive Example 5, in particular, an enlargement of the oxygen precipitation region could be confirmed as a result of an increase in the amount of inwardly diffused oxygen due to the high-temperature, long-period oxidation treatment.

Then, the surface of each of the wafers obtained in Comparative Examples 1 and 2 and Inventive Examples 1 to 5 was intentionally contaminated with 1×10¹²/cm² of nickel, and simplified device thermal simulation was carried out. Then, superficial 3-μm etching was performed using a Wright etching solution, and each wafer surface was observed for surface defects under an optical microscope. As a result, in Comparative Examples 1 and 2, nickel silicide was observed on the silicon surface. In each of Inventive Examples 1 to 5 according the invention, nickel contamination was arrested and no silicide was observed.

As described hereinabove, even when a low oxygen concentration, defect-free wafer is employed, a region increased in oxygen concentration can be formed under the wafer surface by carrying out the high-temperature oxidation heat treatment according to the silicon wafer heat treatment method by the present invention under appropriate conditions to cause inward diffusion of oxygen from the wafer surface. Owing to this, it is possible, by carrying out the subsequent oxygen precipitation heat treatment under optimal conditions, to form a DZ layer on the wafer surface and stably form oxygen precipitates optimal in size at a high density within the wafer so that excellent gettering effects may be produced.

Furthermore, in case of use as SOI substrates formed by SIMOX, the silicon wafer heat treatment method by the present invention can produce the same effects as mentioned above by carrying out the high-temperature oxidation heat treatment under appropriate conditions following oxygen ion implantation in the SIMOX process and carrying out the subsequent oxygen precipitation heat treatment. Thus, the method can be widely applied as a method for heat treatment of low oxygen concentration, defect-free wafers.

What is claimed is:

1. A method for heat treatment of low oxygen concentration silicon wafers having an oxygen concentration of 6.5 to 12×10¹⁷ atoms/cm³ (ASTM F 121-1979) as obtained from a silicon single crystal produced by the Czochralski process, comprising the steps of:
subjecting said silicon wafers to high-temperature oxidation heat treatment for formation of a high oxygen concentration region under a silicon wafer surface; and
subjecting the wafers to oxygen precipitation heat treatment.

2. A method for heat treatment of silicon wafers according to claim 1, wherein said high-temperature oxidation heat treatment is carried out in a gas atmosphere containing not lower than 5% of oxygen at a temperature of 1250° C. to 1380° C. for 1 to 20 hours.

3. A method for heat treatment of silicon wafers according to claim 1, wherein said oxygen precipitation heat treatment comprises heat treatment for the formation of oxygen precipitate nuclei, which is carried out in an atmosphere of oxygen, nitrogen, inert gas, or mixed gas at a temperature of 450° C. to 800° C. for 1 to 48 hours, and heat treatment for the growth of oxygen precipitates, which is carried out in an atmosphere of oxygen, nitrogen, inert gas, or a mixed gas at a temperature of 800 to 1100° C. for 4 to 48 hours.

4. A method for heat treatment of silicon wafers according to claim 1, wherein, prior to said oxygen precipitation heat treatment, said heat treatment is carried out in a nitrogen gas-containing atmosphere at temperature raising and lowering rates of not lower than 20° C./second at a temperature of 1100 to 1300° C. for 1 second to 5 minutes using a rapid thermal annealing heater.

5. A method for heat treatment of silicon wafers according to claim 3, wherein, prior to said oxygen precipitation heat treatment, said heat treatment is carried out in a nitrogen gas-containing atmosphere at temperature raising and lowering rates of at least 20° C./second at a temperature of 1100 to 1300° C. for 1 second to 5 minutes using a rapid thermal annealing heater.

6. A method for heat treatment of silicon wafers according to claim 1, wherein, in case of using said silicon wafers as SOI substrates formed by SIMOX, silicon wafers with an oxygen concentration of not lower than 6.5×10¹⁷ atoms/cm³ (ASTM F 121-1979) are used and said high-temperature oxidation heat treatment is carried out in a gas atmosphere containing not lower than 20% of oxygen at a temperature of 1300° C. to 1380° C. for 4 to 48 hours to form a buried oxide layer subsequent to oxygen ion implantation by the SIMOX technique and, thereafter, the oxygen precipitation heat treatment is carried out.

7. A method for heat treatment of silicon wafers according to claim 6, wherein said oxygen precipitation heat treatment comprises heat treatment for formation of oxygen precipitate nuclei, which is carried out in an atmosphere of oxygen, nitrogen, inert gas, or mixed gas at a temperature of 450° C. to 800° C. for 1 to 48 hours, and heat treatment for growth of oxygen precipitates, which is carried out in an atmosphere of oxygen, nitrogen, inert gas, or mixed gas at a temperature of 800° C. to 1100° C. for 4 to 48 hours.

8. A method for heat treatment of silicon wafers according to claim 6, wherein, prior to said oxygen precipitation heat treatment, said heat treatment is carried out in a nitrogen gas-containing atmosphere at a temperature of 1100 to 1300° C. for 1 second to 5 minutes at temperature raising and lowering rates of not lower than 20° C./second using a rapid thermal annealing heater.

9. A method for heat treatment of silicon wafers according to claim 7, wherein, prior to said oxygen precipitation heat treatment, said heat treatment is carried out in a nitrogen gas-containing atmosphere at a temperature of 1100 to 1300° C. for 1 second to 5 minutes at temperature raising and lowering rates of not lower than 20° C./second using a rapid thermal annealing heater.

10. A method for heat treatment of silicon wafers according to claim 1, wherein silicon wafers obtained from a silicon single crystal comprising a defect-free region where neither aggregates of interstitial silicon type point defects (e.g. dislocation clusters) nor aggregates of vacancy type point defects (e.g. COPs) are present are used.

11. A method for heat treatment of silicon wafers according to claim 6, wherein silicon wafers obtained from a silicon single crystal comprising a defect-free region where neither aggregates of interstitial silicon type point defects (e.g. dislocation clusters) nor aggregates of vacancy type point defects (e.g. COPs) are present are used.

12. A method for heat treatment of silicon wafers according to claim 1, wherein silicon wafers obtained from a silicon single crystal containing nitrogen at a concentration within the range of 1×10¹² to 5×10¹⁵ atoms/cm³ are used.

13. A method for heat treatment of silicon wafers according to claim 6, wherein silicon wafers obtained from a silicon single crystal containing nitrogen at a concentration within the range of 1×10¹² to 5×10¹⁵ atoms/cm³ are used.

14. A method for heat treatment of silicon wafers according to claim 10, wherein silicon wafers obtained from a silicon single crystal containing nitrogen at a concentration within the range of 1×10¹² to 5×10¹⁵ atoms/cm³ are used.

15. A method for heat treatment of silicon wafers according to claim 1, wherein silicon wafers obtained from a silicon single crystal containing carbon at a concentration within the range of 1×10¹⁵ to 5×10¹⁶ atoms/cm³ (ASTM F 123-1981) are used.

16. A method for heat treatment of silicon wafers according to claim 6, wherein silicon wafers obtained from a silicon single crystal containing carbon at a concentration within the range of 1×10¹⁵ to 5×10¹⁶ atoms/cm³ (ASTM F 123-1981) are used.

17. A method for heat treatment of silicon wafers according to claim 10, wherein silicon wafers obtained from a silicon single crystal containing carbon at a concentration within the range of 1×10¹⁵ to 5×10¹⁶ atoms/cm³ (ASTM F 123-1981) are used.

18. A method for heat treatment of silicon wafers according to claim 14, wherein silicon wafers obtained from a silicon single crystal containing carbon at a concentration within the range of 1×10¹⁵ to 5×10¹⁶ atoms/cm³ (ASTM F 123-1981) are used.
